(19) United States
(12) Patent Application Publication
(10) Pub. No.: US 2026/0165088 A1
(43) Pub. Date: Jun. 11, 2026

(54) CONTROL METHOD OF INSPECTION APPARATUS FOR SEMICONDUCTOR

(71) Applicant: PEMTRON Co., Ltd., Seoul (KR)

(72) Inventors: Cheol Hoon CHO, Goyang-si (KR); Jong Vin YIM, Seoul (KR); Nam Soo KIM, Seoul (KR)

(21) Appl. No.: 19/375,164

(22) Filed: Oct. 30, 2025

(30) Foreign Application Priority Data
Dec. 9, 2024 (KR) 10-2024-0181827

(51) Int. Cl. H01L 21/687; G01N 21/88; H01L 21/67; H01L 21/68

(52) U.S. Cl. CPC H10P 72/7612; H10P 72/0616; H10P 72/50; H10P 72/7618; G01N 21/8806; G01N 2021/8822

(57) ABSTRACT

Proposed is a control method of an inspection apparatus for a semiconductor wafer. The control method comprises moving the imaging unit upward by the vertical driving unit when a home sequence is initiated; turning off the servo motor; rotating the wafer chuck, wherein the guide part rotates together with the wafer chuck due to the servo motor turned off; turning on the servo motor; moving the wafer chuck to an initial position thereof by the chuck driving part; moving the imaging unit to an initial position thereof by the horizontal movement module; and moving the lift pins upward and downward by rotating the guide part as the servo motor is driven.

Thereby, collisions between components during operations according to a home sequence, for example, collisions between a dark field illuminator and lift pins of a wafer chuck is prevented.

### CROSS REFERENCE TO RELATED APPLICATION

The present application claims priority to Korean Patent Application No. 10-2024-0181827, filed Dec. 9, 2024, the entire contents of which are incorporated herein for all purposes by this reference.

### BACKGROUND OF THE INVENTION

### Field of the Invention

The present disclosure relates generally to a control method of an inspection apparatus for a semiconductor wafer and, more particularly, to a control method of an inspection apparatus for a semiconductor wafer, in which collision between components is prevented during the movement of the inspection apparatus to an initial position thereof.

### Description of the Related Art

In general, a semiconductor chip is produced by forming fine patterns on a silicon wafer, dicing the wafer into individual units, and then packaging them. By inspecting for defects on or within the wafer, such as dust adhering to the surface of the wafer or scratches formed thereon, or internal defects like air pockets, prior to the formation of the fine patterns, yield can be improved.

Such inspection of the surface and interior of a semiconductor wafer makes it possible to identify which process in the manufacturing line of the semiconductor wafer has a problem. Accordingly, not only can effective countermeasures be established for equipment manufacturing and processes, but yield improvement can also be achieved.

Meanwhile, conventionally, an operator visually examines defects on and within a semiconductor wafer by capturing images with conventional optical equipment, such as a camera, and enlarging images of portions suspected of having defects.

Meanwhile, the semiconductor wafer that have undergone a molding process using resin is inspected for defects before the singulation process. Since the molding process using resin gives the surface a mirror-like feel, a bright field lighting device that illuminates the inspection target with bright field light and a dark field lighting device that illuminates the inspection target with dark field light are used to analyze the images captured by the camera to inspect for defects.

Here, bright field light refers to light irradiated in a vertical direction to the inspection target surface of the semiconductor wafer, and dark field light refers to light irradiated from the side at a certain angle to the inspection target surface.

The dark field method using dark field light detects defects by photographing light directly reflected from the semiconductor wafer, and the bright field method using bright field light detects defects by photographing light diffusely reflected from the semiconductor wafer.

Among these methods, the dark field method receives reflected and scattered light by a collector and represents a point that exhibits a specific intensity (intensity of scattered light) as a defect.

In the case of the bright field method, when the semiconductor wafer molded by resin is inspected, it is easy to measure by the amount of light directly reflected. However, in the case of the dark field method, a dark field light source with high brightness is required to detect diffusely reflected light from the semiconductor wafer molded by resin.

Typically, the dark field light source is used by installing multiple LED modules on the inner wall of a hollow ring-shaped structure, and is positioned close to the semiconductor wafer.

Due to this structure, there is a risk of collision between parts of the inspection device during the home sequence operation process for moving the semiconductor wafer to the initial position and home position for the wafer chuck to be seated, so a home sequence that can prevent collision is required.

### SUMMARY OF THE INVENTION

Accordingly, the present disclosure has been made keeping in mind the above problems occurring in the related art, and the present disclosure is intended to provide a control method of an inspection apparatus for a semiconductor wafer, which can prevent collisions between components during operations according to a home sequence.

In order to achieve the objectives of the present disclosure, there is provided a control method of an inspection apparatus for a semiconductor wafer. The inspection apparatus comprises: a wafer chuck; a plurality of lift pins configured to protrude upward from and be inserted into the wafer chuck, with the semiconductor wafer seated thereon; a guide part rotatably installed inside the wafer chuck and configured to move the lift pins upward and downward as the guide part rotates; a servo motor configured to rotate the guide part; a chuck driving part configured to reciprocate the wafer chuck in a longitudinal direction; an imaging unit configured to image the semiconductor wafer seated on the wafer chuck; a horizontal movement module configured to support the imaging unit so that the imaging unit reciprocates in a transverse direction, with the imaging unit installed on the horizontal movement module; and a vertical driving unit configured to move the imaging unit in a vertical direction with respect to the horizontal movement module. The control method comprises: moving the imaging unit upward by the vertical driving unit when a home sequence is initiated; turning off the servo motor; rotating the wafer chuck, wherein the guide part rotates together with the wafer chuck due to the servo motor turned off; turning on the servo motor; moving the wafer chuck to an initial position thereof by the chuck driving part; moving the imaging unit to an initial position thereof by the horizontal movement module; and moving the lift pins upward and downward by rotating the guide part as the servo motor is driven.

Herein, the turning-on of the servo motor is performed between the rotating of the wafer chuck and the moving of the lift pins upward and downward.

In addition, the imaging unit comprises a dark field illuminator. Tee dark field illuminator is installed on the horizontal movement module, and is not constrained by the vertical movement of the imaging unit driven by the vertical driving unit, but is constrained by movement of the horizontal movement module in the transverse direction.

According to the above configuration, the present disclosure provides a control method of an inspection apparatus for a semiconductor wafer, which can prevent collisions between components during operations according to a home sequence, for example, collisions between a dark field illuminator and lift pins of a wafer chuck.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a perspective view of an inspection apparatus for a semiconductor wafer according to the embodiment of the present disclosure;

FIG. 2 is a front view of the inspection apparatus for a semiconductor wafer according to an embodiment of the present disclosure;

FIGS. 3 to 5 are perspective views of the inspection apparatus for a semiconductor wafer according to an embodiment of the present disclosure, with an imaging unit removed;

FIG. 6 is a side view of the inspection apparatus for a semiconductor wafer according to an embodiment of the present disclosure, with the imaging unit removed;

FIG. 7 is a perspective view of a wafer chuck, as seen from below, according to an embodiment of the present disclosure;

FIG. 8 is a perspective view of the wafer chuck, as seen from above, according to an embodiment of the present disclosure;

FIG. 9 is a view illustrating the arrangement of a plurality of first through-holes and a plurality of second through-holes in an embodiment of the present disclosure;

FIG. 10 is a view illustrating a state in which a plurality of lift pins are installed on a partition plate inside a stage in an embodiment of the present disclosure;

FIG. 11 is a view illustrating a state in which the plurality of lift pins are disposed on a guide part in an embodiment of the present disclosure;

FIG. 12 schematically illustrates a configuration of each of the lift pins according to an embodiment of the present disclosure;

FIG. 12 illustrates a state in which, during the rotation of a guide plate in an embodiment of the present disclosure, a first lift pin is disposed on a first rail and a second lift pin is disposed on a second ridge portion of a second rail;

FIGS. 14A, 14B, and 14C are views illustrating a process in which a first wafer is placed on a plurality of first lift pins and seated on the stage in an embodiment of the present disclosure;

FIGS. 15A, 15B, and 15C are views illustrating a process in which a second wafer is placed on a plurality of second lift pins and seated on the stage in an embodiment of the present disclosure; and

FIG. 16 is a flowchart for explaining a home sequence of the inspection apparatus for a semiconductor wafer according to an embodiment of the present disclosure.

### DETAILED DESCRIPTION OF THE INVENTION

Advantages and features of the present disclosure, as well as methods for achieving them, will become apparent with reference to embodiments described in detail below in conjunction with the accompanying drawings. However, the present disclosure is not limited to the embodiments disclosed below but may be implemented in various other forms. The embodiments are provided merely to make the disclosure of the present disclosure complete and to fully inform those skilled in the art to which the present disclosure pertains of the scope of the present disclosure, and the present disclosure is defined only by the scope of the claims.

The terms used in the present specification are intended to describe the embodiments and are not intended to limit the present disclosure. As used in the present specification, singular forms also include plural forms unless otherwise specified in the context. The terms “comprises” and/or “comprising” used in this specification do not exclude the presence or addition of one or more other components in addition to the stated components. Throughout the specification, the same reference numerals refer to the same components, and “and/or” includes each of the stated components as well as any combination of one or more of them. Although terms such as “first” and “second” are used to describe various components, these components are not limited by these terms. These terms are used merely to distinguish one component from another component. Therefore, a first component mentioned below may be a second component within the technical spirit of the present disclosure.

Unless otherwise defined, all terms (including technical and scientific terms) used in this specification are to be construed as having meanings commonly understood by those skilled in the art to which the present disclosure pertains. In addition, terms that are defined in commonly used dictionaries are not to be interpreted in an idealized or overly formal sense unless explicitly defined otherwise.

Hereinafter, embodiments according to the present disclosure will be described in detail with reference to the accompanying drawings.

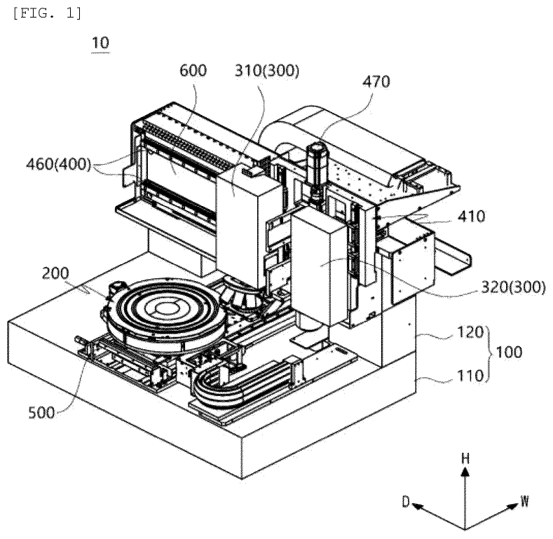

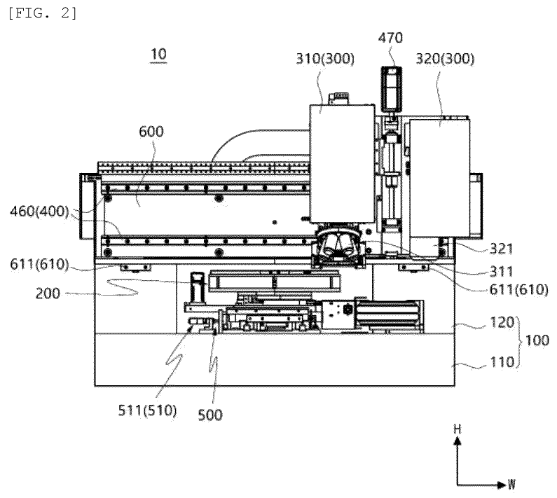

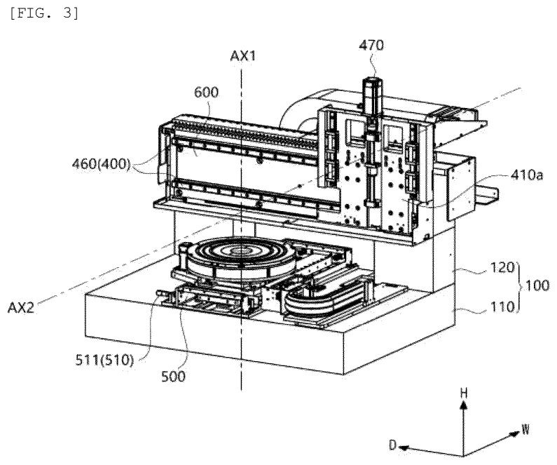

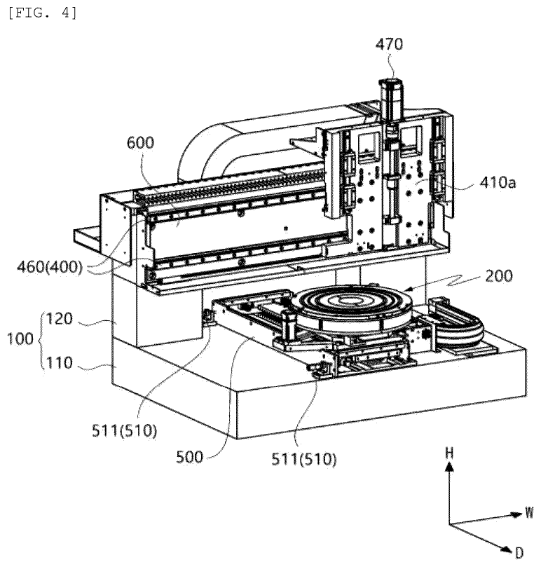

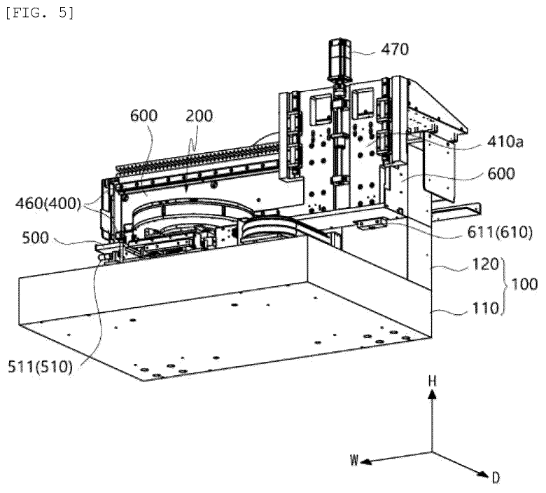

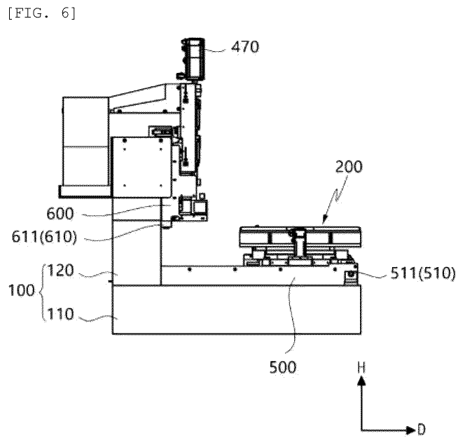

FIG. 1 is a perspective view of an inspection apparatus for a semiconductor wafer according to the embodiment of the present disclosure, FIG. 2 is a front view of the inspection apparatus for a semiconductor wafer according to an embodiment of the present disclosure, FIGS. 3 to 5 are perspective views of the inspection apparatus for a semiconductor wafer according to an embodiment of the present disclosure, with an imaging unit removed, and FIG. 6 is a side view of the inspection apparatus for a semiconductor wafer according to an embodiment of the present disclosure, with the imaging unit removed.

Referring to FIGS. 1 to 6, an inspection apparatus 10 for a semiconductor wafer according to the embodiment of the present disclosure may include a wafer chuck 200, an imaging unit 300, a main body 100, a horizontal movement module 400, a wafer bracket 500, and an imaging bracket 600.

A semiconductor wafer may be seated on the wafer chuck 200 according to the embodiment of the present disclosure. In an embodiment, the wafer chuck 200 may be provided to be movable in at least one direction of a transverse direction W and a longitudinal direction D. For example, the wafer chuck 200 may be provided to be movable in the longitudinal direction D.

Here, the wafer bracket 500 may be provided with a chuck driving part 530 for reciprocating the wafer chuck 200 in the longitudinal direction. In one embodiment, the chuck driving part 530 may include an LM guide and a motor.

The imaging unit 300 according to an embodiment of the present disclosure images the semiconductor wafer seated on the wafer chuck 200. In an embodiment, the imaging unit 300 may include a 2D camera module 310 for capturing a 2D image of the semiconductor wafer, and a 3D camera module 320 for capturing a 3D image of the semiconductor wafer.

Here, the 2D camera module 310 and the 3D camera module 320 may be installed on the wafer bracket 500 so as to be movable in a vertical direction H. In an embodiment, the horizontal movement module 400 may be provided with a vertical driving unit 470 for moving the imaging unit 300 in the vertical direction.

The imaging unit 300 according to an embodiment of the present disclosure may include an objective lens module 311 and a dark field illuminator 330.

Here, the objective lens module 311 moves up and down together with the vertical movement of the imaging unit 300 driven by the vertical driving unit 470, whereas the dark field illuminator 330 is fixed in position in the vertical direction regardless of the vertical movement of the imaging unit 300 driven by the vertical driving unit 470.

This is because the objective lens module 311 according to an embodiment of the present disclosure has a structure in which objective lenses of different magnifications are rotatable in a turret configuration, and due to this turret structure, the rotation of the objective lens module 311 may interfere with a structure for the dark field illuminator 330.

Accordingly, when the rotation of the objective lens module 311 is required, the vertical driving unit 470 may move the imaging unit 300 upward before rotating the objective lens module 311, thereby preventing collision or interference therebetween.

Here, the dark field illuminator 330 is fixedly installed on an imaging mounting module 410 of the horizontal movement module 400, which will be described later, so that the dark field illuminator 330 moves together when the imaging mounting module 410 moves in the transverse direction. During the movement of the imaging mounting module 410 in the transverse direction, the entire imaging unit 300 moves in the transverse direction.

The main body 100 according to an embodiment of the present disclosure may include a horizontal body 110 and a vertical body 120.

The horizontal body 110 constitutes the entire frame of a portion of the main body 100, which is seated on the floor. In an embodiment, the horizontal body 110 is exemplified as having a substantially rectangular parallelepiped shape.

The vertical body 120 extends upward from the horizontal body 110. In the present disclosure, the vertical body 120 extends upward from the upper plate surface of the horizontal body 110, specifically, from the rear edge of the upper plate surface in the longitudinal direction D.

The imaging unit 300 is installed on the horizontal movement module 400 according to an embodiment of the present disclosure. In addition, the horizontal movement module 400 supports the imaging unit 300 so that the imaging unit 300 reciprocates in the transverse direction W, with the imaging unit 300 installed on the horizontal movement module 400.

As described above, in an embodiment of the present disclosure, the imaging unit is composed of the 2D camera module 310 and the 3D camera module 320. When capturing a 2D image by using the 2D camera module 310, the horizontal movement module 400 moves in the transverse direction W so that the 2D camera module 310 is positioned above the wafer chuck 200. In addition, when capturing a 3D image by using the 3D camera module 320, the horizontal movement module 400 moves in the transverse direction W so that the 3D camera module 320 is positioned above the wafer chuck 200.

For another example, when the 2D camera module 310 or the 3D camera module 320 is positioned above the wafer chuck 200, the 2D camera module 310 or the 3D camera module 320 is located close to the semiconductor wafer seated on the wafer chuck 200. Accordingly, when the 2D camera module 310 or the 3D camera module 320 is positioned above the wafer chuck 200, it is difficult to seat the semiconductor wafer on the wafer chuck 200 or to remove the semiconductor wafer from the wafer chuck 200.

In this case, during the transfer of the semiconductor wafer, the imaging unit 300 may be moved in the transverse direction W so that the 2D camera module 310 and the 3D camera module 320 are not positioned above the wafer chuck 200 as shown in FIG. 1.

The wafer chuck 200 is installed on the upper plate surface of the wafer bracket 500 according to an embodiment of the present disclosure. In addition, the wafer bracket 500 is coupled to the upper plate surface of the horizontal body 110 so as to be rotatable by a predetermined angle about an axis Ax1 in the vertical direction H.

Through such a configuration, instead of directly fixing the wafer chuck 200 to the horizontal body 110, the wafer chuck 200 is fixed to the wafer bracket 500, and the wafer bracket 500 is coupled to the horizontal body 110 so as to be rotatable by a predetermined angle about the axis Ax1 in the vertical direction H with respect to the horizontal body 110, and thus the alignment of the wafer chuck 200 may be adjusted about the axis Ax1 in the vertical direction H.

Meanwhile, the horizontal movement module 400 may be installed on the imaging bracket 600. In addition, the imaging bracket 600 may be coupled to the front plate surface of the vertical body 120 so as to be rotatable by a predetermined angle about an axis Ax2 in the longitudinal direction D.

Through such a configuration, instead of directly fixing the horizontal movement module 400 to the vertical body 120, the horizontal movement module 400 is fixed to the imaging bracket 600, and the imaging bracket 600 is coupled to the vertical body 120 so as to be rotatable by a predetermined angle about the axis Ax2 in the longitudinal direction D with respect to the vertical body 120, thereby adjusting the alignment of the imaging unit 300 about the axis Ax2 in the longitudinal direction D.

Through the above configuration, alignment between the wafer chuck 200 and the imaging unit 300 may be adjusted by adjusting the angle of the wafer chuck 200 by using the wafer bracket 500 and by adjusting the angle of the imaging unit 300 by using the imaging bracket 600.

In an embodiment, the inspection apparatus 10 for a semiconductor wafer may include a wafer angle adjusting unit 510 and an imaging angle adjusting unit 610.

The wafer angle adjusting unit 510 according to an embodiment of the present disclosure may adjust the rotation angle of the wafer bracket 500 relative to the horizontal body, that is, the rotation angle of the wafer bracket 500 about the axis Ax1 in the vertical direction H.

In an embodiment, the wafer angle adjusting unit 510 may include one pair of wafer angle adjusting blocks 511 installed on the horizontal body 110 to be spaced apart from each other in the longitudinal direction D. The pair of wafer angle adjusting blocks 511 may move respective opposite sides of the wafer bracket 500 in the longitudinal direction D in opposite directions along the transverse direction W, thereby adjusting the rotation angle of the wafer bracket 500 about the axis Ax1 in the vertical direction H.

In the present disclosure, as an example, each of the wafer angle adjusting blocks 511 adjusts the angle of the wafer bracket 500 by moving the respective opposite sides of the wafer bracket 500 in the longitudinal direction D in opposite directions along the transverse direction W through forward and reverse rotations of an adjustment bolt (not shown).

The imaging angle adjusting unit 610 according to an embodiment of the present disclosure may adjust the rotation angle of the imaging bracket 600 with respect to the vertical body 120.

In an embodiment, the imaging angle adjusting unit 610 may include one pair of imaging angle adjusting blocks 611 installed on the vertical body 120 to be spaced apart from each other in the transverse direction W.

The pair of imaging angle adjusting blocks 611 may move the respective opposite sides of the imaging bracket 600 in the transverse direction W in opposite directions along the vertical direction H, thereby adjusting the rotation angle of the imaging bracket 600 about the axis Ax2 in the longitudinal direction D.

In the present disclosure, as an example, each of the imaging angle adjusting blocks 611 adjusts the angle of the imaging bracket 600 by moving the respective opposite sides of the imaging bracket 600 in the transverse direction W in opposite directions along the vertical direction H through forward and reverse rotations of an adjustment bolt (not shown).

Meanwhile, the horizontal movement module according to an embodiment of the present disclosure may include the imaging mounting module 410 and a guide rail 460.

The imaging unit 300 may be mounted on the imaging mounting module 410 according to an embodiment of the present disclosure. As described above, the imaging unit 300 includes the 2D camera module 310 and the 3D camera module 320, wherein the 2D camera module 310 and the 3D camera module 320 are arranged in the transverse direction W on the imaging mounting module 410.

The guide rail 460 according to an embodiment of the present disclosure may be installed on the front plate surface of the imaging bracket 600 along the transverse direction W. Here, the guide rail 460 guides the reciprocating movement of the imaging mounting module 410 in the transverse direction W.

In an embodiment, in FIGS. 3 to 5, the imaging mounting module 410 is exemplified as being configured in the form of a mounting plate 410a, and the imaging unit 300 is exemplified as being mounted on the plate.

Hereinafter, the structure and operation of the wafer chuck will be described with reference to FIGS. 7 to 14.

Referring to FIGS. 7 to 11, the wafer chuck 200 includes a stage 210, a guide part 220, a plurality of lift pins 230, and a driving part 240.

A semiconductor wafer W is seated on the stage 210. The guide part 220 and the plurality of lift pins 230 are installed in the internal space of the stage 210. The stage 210 is provided with a seating plate 211, a plurality of through-holes 214 and 215, and a partition plate 217.

The seating plate 211 is a portion on which the semiconductor wafer W is seated. The partition plate 217 supports pin bodies 236 of the lift pins, which will be described later. The partition plate 217 is disposed between the seating plate 211 and a guide plate 221.

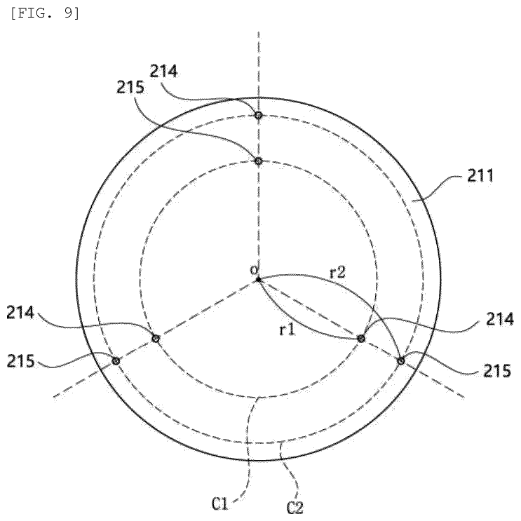

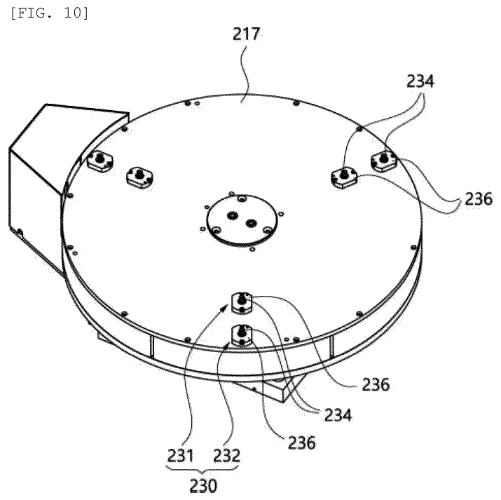

As shown in FIG. 10, the plurality of lift pins 230 are installed on the partition plate 217. Each of the lift pins 230 is installed on the partition plate 217 so that each of the pin bodies 236 is held on an upper surface of the partition plate 217 and an elastic member 238 is positioned beneath the partition plate 217. The pin body 236 is disposed between the seating plate 211 and the partition plate 217.

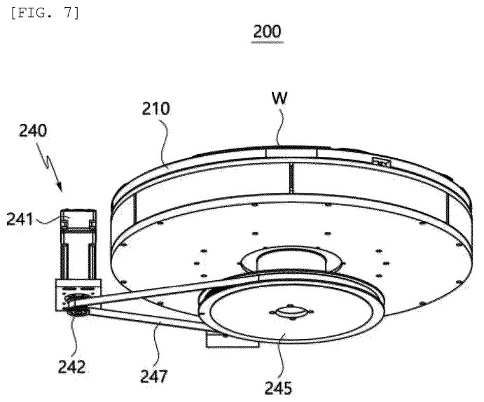

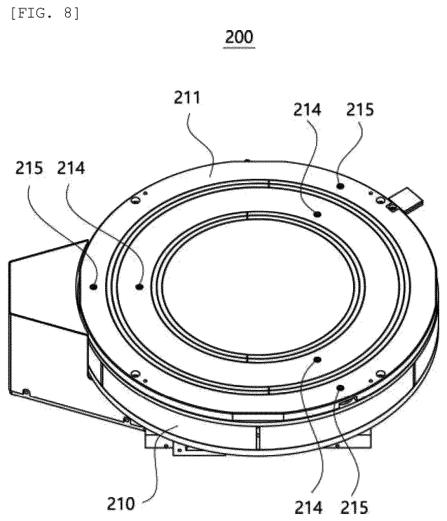

As shown in FIGS. 8 and 9, the plurality of through-holes 214 and 215 are holes formed by penetrating the seating plate 211 vertically. The plurality of through-holes 214 and 215 are provided so that pin supports 234 of the plurality of lift pins 230 pass therethrough.

In this embodiment, for convenience of description, the plurality of through-holes 214 and 215 are respectively referred to as first through-holes 214 and second through-holes 215.

Here, the first through-holes 214 are arranged on an imaginary first concentric circle C1 having a first radius r1 with respect to the center O of the seating plate 211. The plurality of first through-holes 214 are arranged to be spaced apart from each other along the circumferential direction of the first concentric circle C1.

In this embodiment, the plurality of first through-holes 214 are disposed to be spaced apart from each other at intervals of 120 degrees. First lift pins 231, which will be described later are connected to the first through-holes 214.

The second through-holes 215 are arranged on an imaginary second concentric circle C2 having a second radius r2 with respect to the center of the seating plate 211. The plurality of second through-holes 215 are disposed to be spaced apart from each other along the circumferential direction of the second concentric circle C2. In this embodiment, the plurality of second through-holes 215 are disposed to be spaced apart from each other at intervals of 120 degrees.

Each of the second through-holes 215 is disposed to be spaced apart from each of the first through-holes 214 disposed adjacently thereto in a straight line radially from the center of the seating plate 211. Each of the second through-holes 215 is disposed on the imaginary second concentric circle C2.

The second radius r2 is greater than the first radius r1. The first radius r1 and the second radius r2 are determined according to the specifications of the semiconductor wafer W. Second lift pins 232, which will be described later, are connected to the second through-holes 215.

FIG. 11 is a view illustrating a state in which the plurality of lift pins 230 is disposed on the guide part 220.

The guide part 220 is installed in the internal space of the stage 210. The guide part 220 is provided to guide the movement of the plurality of lift pins 230.

As shown in FIG. 11, the guide plate 221 is installed in the internal space of the stage 210. The guide plate 221 is installed in the stage 210 so that the center of the guide plate 221 is coaxially aligned with the center of the stage 210 along a first axial direction A1. In addition, the guide plate 221 is rotatably coupled to the stage 210.

The guide plate 221 has a plurality of rails 222 and 224, having different radii with respect to the center of the guide plate 221, and a plurality of ridge portions 223 and 225 protruding from the respective rails 222 and 224.

In the present embodiment, for convenience of description, the plurality of rails 222 and 224 will be referred to as a first rail 222 and a second rail 224, respectively, according to their radii.

The first rail 222 has the first radius r1. A plurality of first ridge portions 223 are provided on the first rail 222. Each of the first ridge portions 223 is provided to protrude from the first rail 222 in the first axial direction A1 with a predetermined curvature. Accordingly, the first rail 222 is provided to be curved in the first axial direction A1 with respect to the guide plate 221 due to the plurality of first ridge portions 223. Here, the first axial direction A1 is a direction perpendicular to the guide plate 221.

The plurality of first ridge portions 223 are disposed to be spaced apart from each other along the circumferential direction of the first rail 222. Each of the first ridge portions 223 is configured so that the highest point of the first ridge portion 223 is aligned coaxially with the center of each of the first through-holes 214 in the first axial direction A1. Accordingly, the plurality of first ridge portions 223 are disposed to be spaced apart from each other at intervals of 120 degrees.

In the present embodiment, the number of the plurality of first ridge portions 223 may vary depending on the number of the plurality of first through-holes 214 and the number of the first lift pins 231 connected to the respective first through-holes 214, and is not necessarily limited to the example illustrated in the present specification.

The second rail 224 has the second radius r2. A plurality of second ridge portions 225 are provided on the second rail 224. As described above, the second radius r2 is greater than the first radius r1. Accordingly, the second rail 224 is provided on the guide plate 221 so as to surround the first rail 222.

The plurality of second ridge portions 225 are disposed to be spaced apart from each other along the circumferential direction of the second rail 224. The plurality of second ridge portions 225 are arranged to be offset from the respective first ridge portions 223 with respect to the center of the guide plate 221.

Each of the plurality of second ridge portions 225 is provided to protrude from the second rail 224 in the first axial direction A1 with a predetermined curvature. Accordingly, the second rail 224 has a curved structure in the first axial direction A1 with respect to the guide plate 221 due to the plurality of second ridge portions 225.

Each of the second ridge portions 225 is configured so that a highest point of the second ridge portion 225 is aligned coaxially with the center of each of the second through-holes 215 in the first axial direction A1. Accordingly, the plurality of second ridge portions 225 are disposed to be spaced apart from each other at intervals of 120 degrees.

In the present embodiment, the number of the plurality of second ridge portions 225 may vary depending on the number of the plurality of second through-holes 215 and the number of the second lift pins 232 connected to the respective second through-holes 215, and is not necessarily limited to the example illustrated in the present specification.

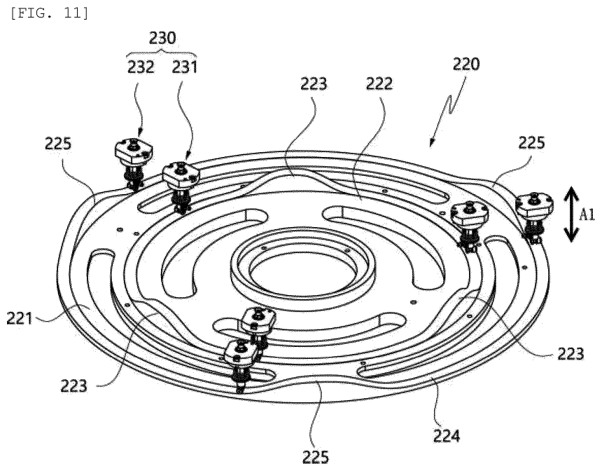

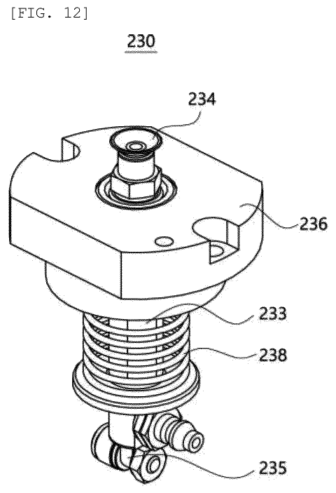

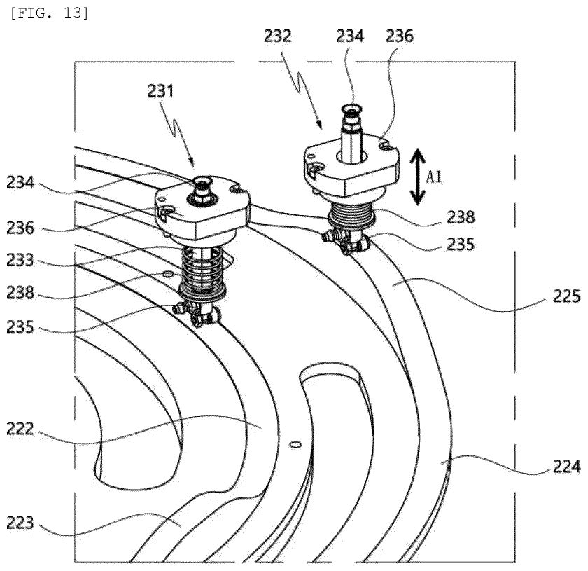

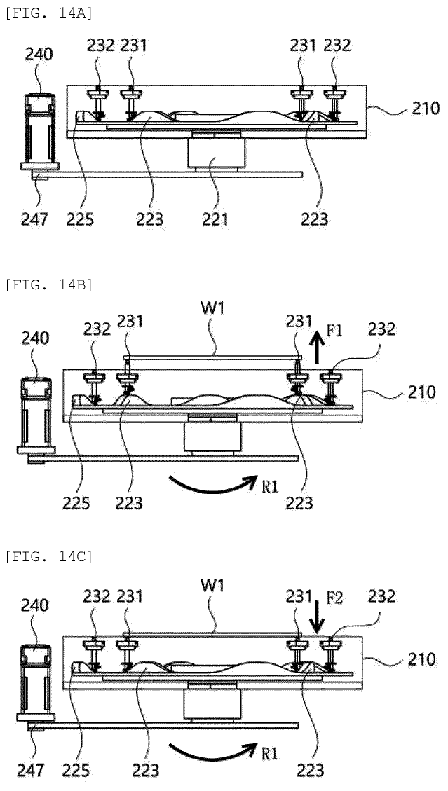

FIG. 12 is a view illustrating configuration of each of the lift pins. FIG. 13 illustrates a state in which, during the rotation of the guide plate, each of the first lift pin is disposed on the first rail, and each of the second lift pin is disposed on the second ridge portion of the second rail. FIGS. 14A, 14B, and 14C are views illustrating a process in which the first wafer is placed on the plurality of first lift pins and seated on the stage.

During operation of the guide part 220, the plurality of lift pins 230 protrude outward from the stage 210 to support the semiconductor wafer W, and are inserted into the interior of the stage 210 so that the semiconductor wafer W is seated on the seating plate 211.

During the rotation of the guide part 220, some of the plurality of lift pins 230 ascend in the first axial direction A1 along the ridge portions 223 and 225 on the rails 222 and 224 and protrude from the seating plate 211 through the through-holes 214 and 215, and then descend in the first axial direction A1 along the ridge portions 223 and 225 and are inserted back into the through-holes 214 and 215.

As shown in FIG. 12, the lift pin 230 includes a pin shaft 233, the pin support 234, a pin roller 235, the pin body 236, and the elastic member 238.

The pin support 234 is configured to support the semiconductor wafer W. The pin support 234 is coupled to the upper end of the pin shaft 233. The pin support 234 is provided to pass through the through-hole 214 or 215 when the lift pin 230 moves upward in the F1 direction. The pin support 234 has an outer diameter smaller than that of the through-hole 214 or 215.

The pin body 236 is coupled to the pin shaft 233 so as to surround the outer circumferential surface of the pin shaft 233. The pin body 236 has an outer diameter larger than that of the through-holes 214 or 215. When the lift pin 230 moves upward in the F1 direction, the pin body 236 is configured to allow only the pin support 234 to pass through the through-holes 214 or 215.

The pin body 236 is disposed between the seating plate 211 and the partition plate 217 and guides the movement of the pin shaft 233 in the first axial direction A1.

The pin roller 235 is coupled to the lower end of the pin shaft 233. The pin roller 235 is in contact with the surface of the rail 222 or 224. During the rotation of the guide plate 221, the pin roller 235 freely rolls along the surface of the rail 222 or 224, transmitting the rotational force of the guide plate 221 to the pin shaft 233. Accordingly, the lift pin 230 moves upward or downward in the first axial direction A1 according to the curvature of the rail 222 or 224.

The elastic member 238 is positioned between the pin body 236 and the pin roller 235 and is coupled to the pin shaft 233 so as to surround the outer circumferential surface of the pin shaft 233.

The elastic member 238 is elastically compressed in the first axial direction A1 as the lift pin 230 ascends along the ridge portion 223 or 225 of the rail 222 or 224. Conversely, the elastic member 238 is elastically decompressed in the first axial direction A1 as the lift pin 230 descends along the ridge portion 223 or 225 of the rail 222 or 224.

In the present embodiment, for convenience of description, the plurality of lift pins 230 are referred to as the first lift pins 231 and the second lift pins 232 depending on their installation positions.

As shown in FIGS. 11 and 13, the first lift pins 231 are configured to receive a first semiconductor wafer W having the first radius r1 from a carrier (not shown) and place it on the stage 210. The plurality of first lift pins 231 are arranged on the imaginary first concentric circle C1 having the first radius r1.

The first lift pins 231 are installed on the first rail 222. The first lift pins 231 connect the first rail 222 and the first through-holes 214 in the first axial direction A1.

As shown in FIG. 14, the plurality of first lift pins 231 are fixed at positions corresponding to the respective first through-holes 214, and during the rotation of the guide plate 221, the plurality of first lift pins 231 are operated to move upward in the F1 direction or downward in an F2 direction along the first axial direction A1.

When the plurality of first lift pins 231 move upward in the F1 direction along the first axial direction A1, the plurality of second lift pins 232 are disposed within the internal space of the stage 210.

Specifically, during rotation of the guide plate 221 in a first rotational direction R1, each of the first lift pins 231 ascends in the F1 direction along the first axial direction A1 while moving upward along each of the first ridge portions 223 of the first rail 222.

The pin support 234 of the first lift pin 231 protrudes from the seating plate 211 of the stage 210 through each of the first through-holes 214 to support the edge of the first semiconductor wafer W having the first radius r1. The pin support 234 protrudes from the seating plate 211 by the height of the first ridge portion 223 at the position where the pin roller 235 contacts the first ridge portion 223.

In addition, each of the first lift pins 231 descends in the F2 direction along the first axial direction A1 while moving downward along each of the first ridge portions 223 of the first rail 222. Accordingly, each of the first lift pins 231 is inserted into each of the first through-holes 214, allowing the first semiconductor wafer W to be seated on the seating plate 211.

As shown in FIGS. 11 and 13, the second lift pins 232 are configured to receive a second semiconductor wafer W having a second radius r2 from a carrier (not shown) and place it on the stage 210. The second lift pins 232 are installed on the second rail 224. The second lift pins 232 connect the second rail 224 and the second through-holes 215 in the first axial direction A1.

Each of the second lift pins 232 is disposed to be spaced apart from each of the adjacent first lift pins 231 disposed adjacently thereto on a straight line radially from the center of the guide plate 221. The plurality of second lift pins 232 are arranged on the imaginary second concentric circle C2 having the second radius r2.

As shown in FIGS. 14A, 14B, and 14C, the plurality of second lift pins 232 are fixed at positions corresponding to the respective second through-holes 215, and during rotation of the guide plate 221, the plurality of second lift pins 232 are operated to move upward in the F1 direction or downward in the F2 direction along the first axial direction A1.

When the plurality of second lift pins 232 move upward in the F1 direction along the first axial direction A1, the plurality of first lift pins 231 are disposed within the internal space of the stage 210.

Specifically, during the rotation of the guide plate 221 in a second rotational direction R2, each of the second lift pins 232 ascends in the F1 direction along the first axial direction A1 while moving upward along each of the second ridge portions 225 of the second rail 224.

Accordingly, each of the second lift pins 232 protrudes from the seating plate 211 of the stage 210 through each of the second through-holes 215 to support the edge of the second semiconductor wafer W having the second radius r2.

In addition, each of the second lift pins 232 descends in the F2 direction along the first axial direction A1 while moving downward along each of the second ridge portions 225 of the second rail 224. Accordingly, each of the second lift pins 232 is inserted into each of the second through-holes 215, allowing the second semiconductor wafer W to be seated on the seating plate 211.

As shown in FIG. 7, the driving part 240 is coupled to the guide plate 221 to provide rotational force to the guide plate 221. The driving part 240 includes a servo motor 241, a rotation transmission part 245, and a drive belt 247.

The rotation transmission part 245 is coupled to a central shaft of the guide plate 221. The drive belt 247 is connected to the rotation shaft 242 of a drive motor and the rotation transmission part 245. The drive belt 247 rotates the rotation transmission part 245 in the rotational direction of the rotation shaft 242 of the drive motor. The guide plate 221 is rotated in the rotational direction of the rotation shaft 242 of the drive motor by the rotation transmission part 245.

FIGS. 14A, 14B, and 14C are views illustrating a process in which the first wafer is placed on the plurality of first lift pins and seated on the stage in an embodiment of the present disclosure.

In the present embodiment, when the first semiconductor wafer W is transported to the wafer chuck 200 by the carrier (not shown), the driving part 240 operates so that the servo motor 241 rotates in the first rotational direction R1. The drive belt 247 transmits the rotational force of the servo motor 241 to the central shaft of the guide plate 221. The guide plate 221 is rotated in the first rotational direction R1.

As illustrated in FIG. 14B, when the guide plate 221 rotates in the first rotational direction R1, each of the first lift pins 231 ascends along the first axial direction A1 in the F1 direction while riding up each of the first ridge portions 223 along the first rail 222. Accordingly, the pin support 234 of each of the first lift pins 231 protrudes from the seating plate 211 of the stage 210 through each of the first through-holes 214, and the first semiconductor wafer W is seated on the pin support 234 of each of the lift pins 230.

As illustrated in FIG. 14C, when the guide plate 221 rotates in the first rotational direction R1 while the first semiconductor wafer W is seated on the pin support 234 of each of the first lift pins 231, each of the first lift pins 231 descends in the F2 direction along the first axial direction A1 while moving down each of the first ridge portions 223 along the first rail 222. As the pin support 234 of each of the first lift pins 231 is inserted into each of the first through-holes 214, the first semiconductor wafer W is seated on the seating plate 211 of the stage 210.

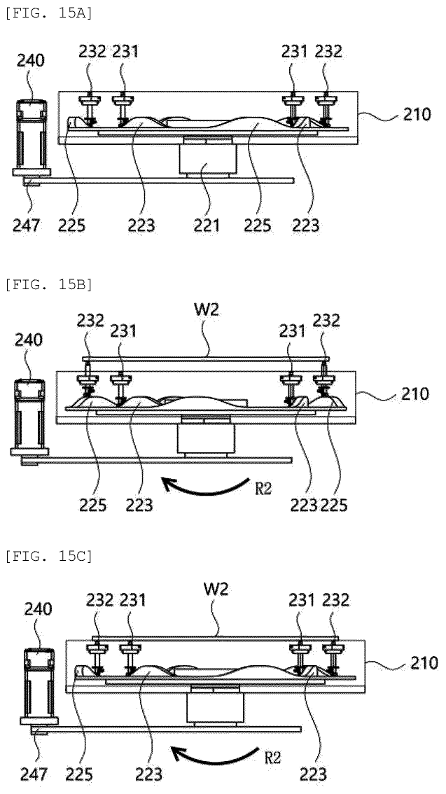

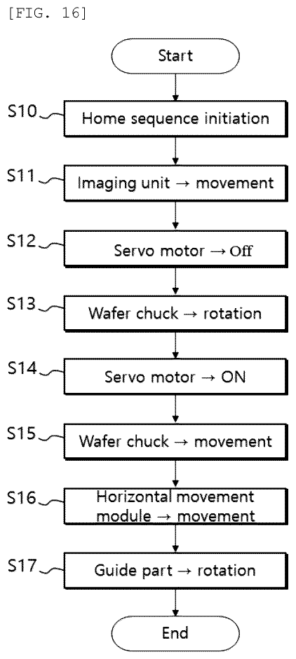

FIGS. 15A, 15B, and 15C are views illustrating a process in which a second wafer is placed on a plurality of second lift pins and seated on the stage in an embodiment of the present disclosure.

In this embodiment, when the second semiconductor wafer W is transferred to the wafer chuck 200 by the carrier (not shown), the driving part 240 operates such that the servo motor 241 rotates in the second rotational direction R2. The drive belt 247 transmits the rotational force of the servo motor 241 to the central shaft of the guide plate 221. The guide plate 221 rotates in the second rotational direction R2.

As shown in FIG. 15B, when the guide plate 221 rotates in the second rotational direction R2, each of the second lift pins 232 ascends in the F1 direction along the second axial direction A2 while moving up along each of the second ridge portions 225 along the second rail 224. Accordingly, the pin support 234 of each of the second lift pins 232 protrudes from the seating plate 211 of the stage 210 through each of the second through-hole 215, and the second semiconductor wafer W is seated on the pin support 234 of each of the lift pins 230.

As shown in FIG. 15C, when the guide plate 221 rotates in the second rotational direction R2 while the second semiconductor wafer W is seated on the pin support 234 of each of the second lift pins 232, each of the second lift pins 232 descends in the F2 direction along the second axial direction A2 while moving downward along each of the second ridge portions 225 along the second rail 224.

The second semiconductor wafer W is seated on the seating plate 211 of the stage 210 as the pin support 234 of each of the respective second lift pins 232 is inserted into each of the second through-holes 215.

Meanwhile, according to an embodiment of the present disclosure, the wafer chuck 200 may exemplarily be coupled to the wafer bracket 500 such that the entire wafer chuck 200 is rotatable about the vertical direction H. In an embodiment, for example, the wafer chuck 200 may be rotatably coupled about the axis of the vertical direction H by a motor (not shown).

Hereinafter, a home sequence in which the inspection apparatus 10 for the semiconductor wafer W having the above configuration according to an embodiment of the present disclosure moves to an initial position, for example, a home position, to seat a new semiconductor wafer W will be described with reference to FIG. 16.

For example, when in a current inspection state, the 2D camera module 310 is positioned above the wafer chuck 200, and the dark field illuminator 330 is positioned on a lower portion of the 2D camera module 310. In this case, it is permissible for the semiconductor wafer W to remain seated on the wafer chuck 200.

In the above state, when the home sequence is initiated in S10, the imaging unit 300 first moves upward in S11.

Next, before the wafer chuck 200 rotates, the servo motor 241 is turned off. As described above, the guide part 220, which is rotated by the servo motor 241, rotates relative to the wafer chuck 200 inside the wafer chuck 200. In this case, if the guide part 220 is constrained by the servo motor 241, when the wafer chuck 200 rotates, the guide part 220 rotates relatively, which may inadvertently cause the lift pins 230 to ascend along the ridge portions 223 and 225.

In this way, when the lift pins 230 ascend along the ridge portions 223 and 225 due to the rotation of the wafer chuck 200, the lift pins 230 or the semiconductor wafer W seated on the lift pins 230 may collide with the dark field illuminator 330, causing damage. To prevent this, the servo motor 241 that constrains the guide part 220 is turned off before the wafer chuck 200 rotates, preventing the guide part 220 from rotating together with the wafer chuck 200 and the lift pins 230 from ascending.

As described above, when the servo motor 241 is turned off in S12, the wafer chuck 200 rotates in S13. Here, the wafer chuck 200 rotates in a rotation direction for seating and removing the semiconductor wafer W, that is, to the initial rotational position.

Then, when the rotation of the wafer chuck 200 is completed, the servo motor 241 is turned on again in S14. In addition, the wafer chuck 200 moves in the longitudinal direction D to a position at which the semiconductor wafer W is seated in S15.

As described above, when the wafer chuck 200 moves away from the inspection position, the horizontal movement module 400 moves in the transverse direction W to move away from the inspection position in S16. In this case, the dark field illuminator 330 also moves together with the movement of the horizontal movement module 400.

In addition, as the servo motor 241 is driven, the guide part 220 rotates in S17, and as the guide part 220 rotates, the lift pins 230 are raised, allowing the semiconductor wafer W to be removed from the wafer chuck 200 or a new semiconductor wafer W to be seated thereon.

Here, the process of turning the servo motor 241 on may be performed before S17.

Although some embodiments of the present disclosure have been illustrated and described, those skilled in the art to which the present disclosure pertains will recognize that the embodiments may be modified without departing from the principles and spirit of the present disclosure. The scope of the present disclosure is defined by the appended claims and their equivalents.

What is claimed is:

1. A control method of an inspection apparatus for a semiconductor wafer, wherein the inspection apparatus comprises:
a wafer chuck; a plurality of lift pins configured to protrude upward from and be inserted into the wafer chuck, with the semiconductor wafer seated thereon; a guide part rotatably installed inside the wafer chuck and configured to move the lift pins upward and downward as the guide part rotates; a servo motor configured to rotate the guide part; a chuck driving part configured to reciprocate the wafer chuck in a longitudinal direction; an imaging unit configured to image the semiconductor wafer seated on the wafer chuck; a horizontal movement module configured to support the imaging unit so that the imaging unit reciprocates in a transverse direction, with the imaging unit installed on the horizontal movement module; and a vertical driving unit configured to move the imaging unit in a vertical direction with respect to the horizontal movement module,
wherein the control method comprises:
moving the imaging unit upward by the vertical driving unit when a home sequence is initiated;
turning off the servo motor;
rotating the wafer chuck, wherein the guide part rotates together with the wafer chuck due to the servo motor turned off;
turning on the servo motor;
moving the wafer chuck to an initial position thereof by the chuck driving part;
moving the imaging unit to an initial position thereof by the horizontal movement module; and
moving the lift pins upward and downward by rotating the guide part as the servo motor is driven.

2. The control method of claim 1, wherein the turning-on of the servo motor is performed between the rotating of the wafer chuck and the moving of the lift pins upward and downward.

3. The control method of claim 1, wherein the imaging unit comprises a dark field illuminator,
wherein the dark field illuminator is installed on the horizontal movement module, and is not constrained by the vertical movement of the imaging unit driven by the vertical driving unit, but is constrained by movement of the horizontal movement module in the transverse direction.
